(19) United States
(12) Patent Application Publication
(10) Pub. No.: US 2007/0049017 A1
(43) Pub. Date: Mar. 1, 2007

(54) PLUG FABRICATING METHOD FOR DIELECTRIC LAYER

(76) Inventor: Chao-Ching Hsieh, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,088

(22) Filed: Aug. 29, 2005

(51) Int. Cl. H01L 21/44

(52) U.S. Cl. 438/672

(57) ABSTRACT

A method of fabricating a plug for a hole in a dielectric layer is disclosed. The method includes a first deposition process to partially filling the hole with a conductive material. Later, an etching process is performed at the partially filled hole. In addition, a second deposition process is performed to partially fill the hole with the conductive material again. Finally, the above steps are repeated until the hole is completely filled. The first deposition process and the second deposition process are done using a CVD or a PVD process. In addition, the etching process is done using halogen-containing gas.

### BACKGROUND OF THE INVENTION

1. Field of Invention

The present invention relates to a method of fabricating a plug in a dielectric layer. More particularly, the present invention relates to a method of fabricating a plug in a dielectric layer having improved gap fill properties.

2. Description of Related Art

As the semiconductor device size continues to shrink geometrically, the contact hole is becoming smaller and smaller. The atomic layer deposition (ALD) and pulsed nucleation layer (PNL) deposition methods are used as the current approaches for improving the gap fill using tungsten.

Because the shrinking device size is creating a tendency to result in the greater shrinkage in the horizontal dimension than in the vertical dimension, the increased aspect ratios (height to width) of the devices are making it increasingly important to develop processes that enable conductive material to fill increasing aspect ratio trenches and via holes. In high aspect ratio contact structures, the bulk deposition is also faced with the gap fill problem and the tungsten seams becomes more serious.

Continuous and complete sidewalls, bottom coverage of the seed layer inside very narrow gaps, pinches-off or seals of the small openings when used at thicknesses required on the field for a low-resistance electrical path are all provided by the ALD. As a result, the layers made by ALD are too thin on the field and too thick inside the very narrow gaps. A better method for fabricating a plug in a dielectric having improved gap fill properties is required for the aforementioned smaller contact hole and gaps.

### SUMMARY OF THE INVENTION

An objective for the present invention is for providing a method of fabricating a plug in a dielectric layer having improved gap fill properties and reduced key hole.

Based on the above objective, the present invention proposes a method of fabricating a plug in a dielectric layer having a hole formed therein which has four main steps, namely a first deposition step, an etching step, a second deposition step, and the repeating of the aforementioned consecutive steps, if necessary, until the hole is filled.

The aforementioned method includes a first deposition process for partially filling the hole with a conductive material, a first etching process for removing the overhang and pinch-off portions, a second deposition process for partially filling the hole with a conductive material, and a repeat of all of the aforementioned steps consecutively until the hole is completely filled with the conductive material.

The first deposition process includes a CVD, a PVD, and a high density plasma deposition process. It is performed until an overhang is formed on the top of the hole. The conductive material for the first deposition process includes tungsten, copper, or aluminum.

The first etching process is a dry etching process or a wet etching process. The dry etching process using a halogen-containing gas as a source gas. The halogen-containing gas is, for example, a fluorine-containing gas or a NF₃. The wet etching process is performed, for example, using hydrogen peroxide.

The second deposition process includes a CVD process, a PVD process, and a high density plasma deposition process. It is also performed until an overhang is formed on the top of the hole. The conductive material for the second deposition process includes tungsten, copper, or aluminum.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are cross-sectional views, schematically illustrating a method for fabricating a plug according to a first embodiment of the present invention.

FIG. 2A to FIG. 2C are cross-sectional views, schematically illustrating a method for fabricating a plug according to a second embodiment of the present invention.

### DESCRIPTION OF THE PREFERRED EMBODIMENTS

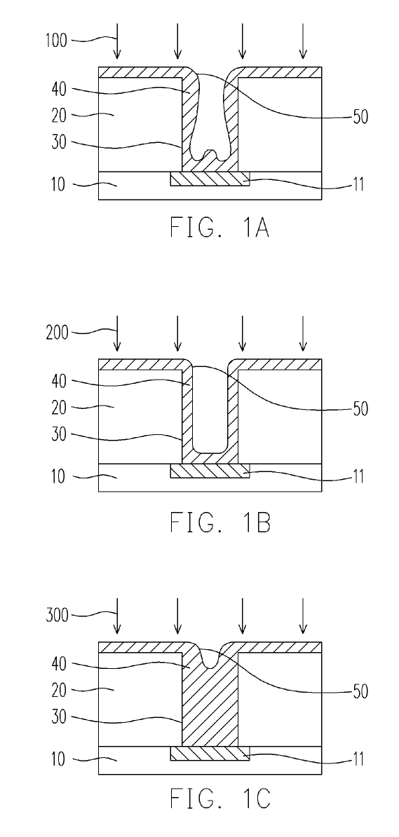

FIG. 1A to FIG. 1C schematically illustrate a multi-deposition-and-etching-step method for fabricating a plug according to a first embodiment of the present invention. The method of fabricating the plug in a dielectric layer 20 for filling a hole 30 for the first embodiment of the present invention comprises the steps as the following.
a. a first deposition process (step 100) is performed to partially fill the hole 30 with a conductive material 40;
b. a first etching process (step 200) is performed;
c. a second deposition process (step 300) is performed to partially fill the hole 30 with a conductive material 40; and
d. repeating step a, b, and c above until the hole 30 is filled with the conductive material 40.

Referring to FIG. 1A, in this embodiment, the hole 30 exposes the device 11, such as conductive region, wire or via, formed in the process layer 10 under the dielectric layer 20. However, the hole 30 in present invention is not limited by the configuration shown in FIG. 1A and can be any other structure, such as trench, without exposing the device formed in the underlayer. Moreover, the first deposition process (step 100) can be a CVD, a PVD, or a high density plasma process. The first deposition process (step 100) is performed until an overhang 50 is formed on the top of the hole 30. The conductive material 40 used in the first deposition process (step 100) includes tungsten, copper, or aluminum.

As shown in FIG. 1B, the first etching process (step 200) can be a dry etching process or a wet etching process. In the dry etching process (step 210), the first etching process (step 200) is performed using a halogen-containing gas as a source gas. The halogen-containing gas includes, for example, a fluorine-containing gas. Preferably, the fluorine-containing gas is a NF₃ gas. While the first etching process (step 200) is the wet etching process, the first etching process (step 200) is performed using a wet etching agent such as hydrogen peroxide.

Referring to FIG. 1C, the second deposition process (step 300) can be a CVD, a PVD, or a high density plasma process. The second deposition process (step 300) is performed until an overhang 50 is formed on the top of the hole 30.

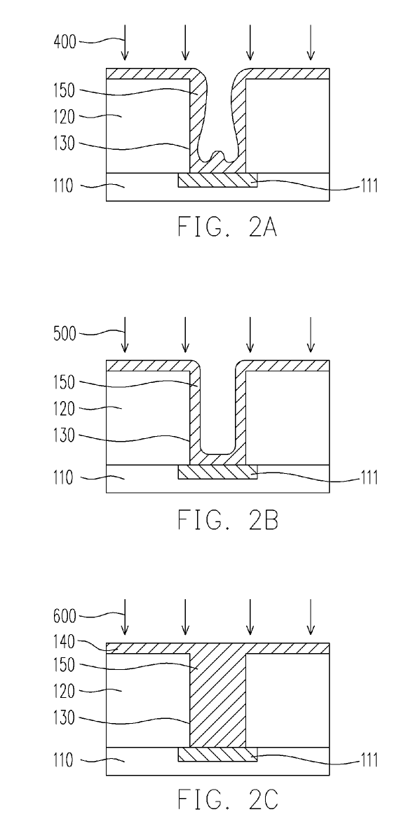

FIG. 2A to FIG. 2C schematically illustrate another 3-step method for fabricating a plug according to a second embodiment of the present invention. The method of fabricating the plug in a dielectric layer 120 for filling a hole 130 corresponding in the second embodiment of the present invention comprises the steps as followings:
a. a first deposition process (step 400) is performed to partially fill the hole with a conductive material 150;
b. an etching process (step 500) is performed; and
c. a second deposition process (step 600) is performed to fill out the hole with a conductive material 150.

Referring to FIG. 2A, in this embodiment, the hole 130 exposes the device 111, such as conductive region, wire or via, formed in the process layer 110 under the dielectric layer 120. However, the hole 130 in present invention is not limited by the configuration shown in FIG. 2A and can be any other structure, such as trench, without exposing the device formed in the underlayer. Furthermore, the first deposition process (step 400) can be a CVD, a PVD, or a high density plasma process. The first deposition process (step 400) is performed to form a conductive layer 140 partially filling the hole 130. The conductive material 150 used for forming the conductive layer 140 in the first deposition process (step 400) includes tungsten, copper, or aluminum.

Referring to FIG. 2B, the etching process (step 500) can be a dry etching process or a wet etching process. While the etching process is the dry etching process, the etching process is performed using a halogen-containing gas as a source gas. The halogen-containing gas includes, for example, a fluorine-containing gas. Preferably, the fluorine-containing gas can be, for example but not limited to, a NF₃ gas. While the etching process is the wet etching process, the etching process is performed using a wet etching agent 190 such as hydrogen peroxide.

Referring to FIG. 2C, the second deposition process (step 600) can be a CVD, a PVD, or a high density plasma process. The second deposition process (step 600) is performed until the hole 130 is filled.

The present invention provides a multi-deposition-and-etching-step method of fabricating a plug in a dielectric layer. By using the method of the present invention, since the overhangs of the conductive layer at the top of the hole formed in the previous deposition process is removed by the successively performed etching process, issue of gap void in the narrow hole during the gap filling can be successfully overcome. Hence, the no keyhole or seam happens during gap filling an opening with a higher aspect ratio.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method of fabricating a plug in a dielectric layer, wherein the dielectric layer has a hole, the method comprising:
a. performing a first deposition process to partially fill the hole with a conductive material;
b. performing a first etching process;
c. performing a second deposition process to partially fill the hole with the conductive material; and
d. repeating step a, b, and c until the hole is filled with the conductive material.

2. The method of claim 1, wherein the first deposition process is performed until an overhang is formed on the top of the hole.

3. The method of claim 1, wherein the first deposition process includes a CVD process, a PVD process, and a high density plasma deposition process.

4. The method of claim 1, wherein, the first etching process includes a dry etching process.

5. The method of claim 4, wherein, the first etching process is performed using a halogen-containing gas as a source gas.

6. The method of claim 1, wherein the second deposition process is performed until an overhang is formed on the top of the hole.

7. The method of claim 1, wherein the second deposition process includes a CVD process, a PVD process, and a high density plasma deposition process.

8. The method of claim 5, wherein the halogen-containing gas comprises a fluorine-containing gas.

9. The method of claim 5, wherein the halogen-containing gas is NF3.

10. The method of claim 1, wherein the first etching process comprises a wet etching process.

11. The method of claim 10, wherein the first etching process is performed by using hydrogen peroxide.

12. The method of claim 1, wherein the conductive material includes tungsten, copper, or aluminum.

13. A method of fabricating a plug in a dielectric layer, wherein the dielectric layer has a hole, comprising:
performing a first deposition process to partially fill the hole with a conductive material;
performing an etching process; and
performing a second deposition process to fill out the hole with conductive material.

14. The method of claim 13, wherein the first deposition process is performed until an overhang is formed on the top of the hole.

15. The method of claim 13, wherein the first deposition process includes a CVD process, a PVD process, and a high density plasma deposition process.

16. The method of claim 13, wherein, the etching process includes a dry etching process.

17. The method of claim 16, wherein, the etching process is performed using a halogen-containing gas as a source gas.

18. The method of claim 13, wherein the second deposition process includes a CVD process, a PVD process, and a high density plasma deposition process.

19. The method of claim 17, wherein the halogen-containing gas comprises a fluorine-containing gas.

20. The method of claim 17, wherein the halogen-containing gas is NF3.

21. The method of claim 13, wherein the etching process comprises a wet etching process.

22. The method of claim 21, wherein the etching process is performed by using hydrogen peroxide.

23. The method of claim 13, wherein the conductive material includes tungsten, copper, or aluminum.
